(19) United States
(12) Patent Application Publication
(10) Pub. No.: US 2020/0410905 A1
(43) Pub. Date: Dec. 31, 2020

(54) PACKAGING LABEL AND METHOD FOR LABELLING A PACKAGE

(71) Applicants: FONDAZIONE ISTITUTO ITALIANO DI TECNOLOGIA, Genova (IT); POLITECNICO DI MILANO, Milano (IT)

(72) Inventors: Marco CARVELLI, Milano (IT); Antonio IACCHETTI, Castellone (IT); Giorgio DELL'ERBA, Bari (IT); Mario CAIRONI, Milano (IT)

(21) Appl. No.: 17/016,177

(22) Filed: Sep. 9, 2020

Related U.S. Application Data
(63) Continuation-in-part of application No. 15/574,033, filed on Nov. 15, 2017.

(30) Foreign Application Priority Data
May 20, 2015 (IT) 102015000016245

(51) Int. Cl. G09F 3/20; H01L 51/00; H01L 51/05; H01L 29/786; H01L 51/42; H01L 27/28; G02F 1/163; G02F 1/1333; G09F 3/02; G09F 9/30

(52) U.S. Cl. CPC G09F 3/208; G02F 2001/13324; H01L 51/0028; H01L 51/0097; H01L 51/0541; H01L 29/7869; H01L 51/4253; H01L 27/283; H01L 27/286; H01L 27/288; G02F 1/163; G02F 1/133305; G09F 3/02; G09F 9/301; H01L 51/0004

(57) ABSTRACT

In an embodiment, the present disclosure pertains to a packaging label (1) comprising a substrate (10), a display (6) placed above the substrate (10), a control module (4) placed in electrical contact with the display (6) and adapted to control the operation of said display (6), at least one photovoltaic module (2) placed above the substrate (10) and next to the display (6) and predisposed to supply the display (6) and the control module (4); wherein the photovoltaic module (2), the control module (4) and the display (6) are printed on the substrate (10) using a printing ink mixed with dopants.

### CROSS-REFERENCE TO RELATED APPLICATIONS

This patent application is a continuation-in-part of U.S. patent application Ser. No. 15/574,033 filed on Nov. 15, 2017. U.S. patent application Ser. No. 15/574,033 is a National Stage Entry of International Patent Application No. PCT/EP2016/061324 filed on May 19, 2016, which claims priority to Italian Patent Application No. 102015000016245, filed on May 20, 2015. This patent application claims priority from, and incorporates by reference the entire disclosure of, U.S. patent application Ser. No. 15/574,033, International Patent Application No. PCT/EP2016/061324, and Italian Patent Application No. 102015000016245.

### TECHNICAL FIELD

The present invention relates to a packaging label and to a method for labelling a package.

### BACKGROUND

In the packaging industry labels with fixed graphics are known, i.e. bearing a predetermined message, which may be adhesive or printed directly onto the packaging, for example a plastic or glass bottle.

However, such labels have the disadvantage of being able to produce only one message (e.g. product name, list of ingredients, or a promotional message), therefore for many commercial products, it is necessary to use a plurality of different labels, each dedicated to specific contents.

In the field of electronics on plastic, dynamic labels are also known, provided with a display for displaying a plurality of different messages, such as, for example, a promotional message, the expiry date and/or the ingredients of the packaged product. However, such labels are not fully comprised of materials compatible with recycling (including the display) and the production process is not compatible with high performance printing or with direct printing on the packaging container. Furthermore, such labels must be self-supplied and not even the supply unit satisfies the above indicated requirements.

Therefore, there is a need to find innovative solutions to the problem of “dynamically” labelling packaged products, mainly for marketing and advertising purposes.

### SUMMARY OF THE INVENTION

The object of the invention is therefore to propose a dynamic label able to progressively change the contents displayed, which may be directly printed and/or integrated onto the packaging and which is compatible with current packaging production processes, by adding to the packaging itself a negligible cost in order to be economically sustainable.

A further object of the invention is that of proposing an easily recyclable label.

These and other objects are reached with a label whose characteristics are defined in claim 1.

Particular embodiments form the subject matter of the dependent claims, whose contents are to be considered an integral part of the present description.

### BRIEF DESCRIPTION OF THE DRAWINGS

Further characteristics and advantages of the invention will appear from the following detailed description, given by way of non-limitative example, with reference to the appended drawings, in which:

FIG. 1 is a schematic front view of a label according to the present invention;

FIG. 2 illustrates a front view of an embodiment of the label of FIG. 1;

FIG. 3 shows a sectional view of the label of FIG. 1;

FIG. 4 shows a variation of the label according to the present invention;

FIG. 5 shows a block diagram of the operations of the method for obtaining a label according to the present invention; and

FIGS. 6-12 show possible embodiments of the present invention.

### DETAILED DESCRIPTION

In summary, a label according to the present invention is fully recyclable, can be printed with high performance printing processes either on plastic or on paper or directly on plastic packaging, for example polyethylene terephthalate (PET), and can be used with the current packaging industry standards. The label according to the present invention also integrates a source of independent energy.

The invention proposes a cost-effective dynamic packaging label, able to update its appearance, that can be directly printed on the packaging material itself (that becomes the substrate of the label) or it can be printed on a different flexible substrate and then be applied to the package with known labeling processes.

The dynamic label comprises:
1) a flexible substrate;
2) a display printed on the flexible substrate;
3) a control module printed on the flexible substrate; and
4) one or more (at least one) photovoltaic module printed on the flexible substrate.

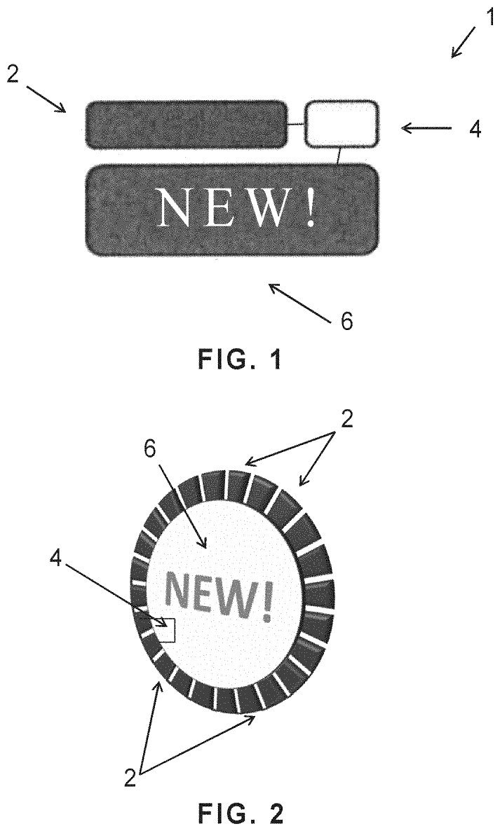

FIG. 1 shows a schematic front view of a label 1 according to the present invention. The substrate can be the package itself, on top of which the label can be printed with all its components. In this sense the external surface of the packaging material (plastic, paper, etc.) becomes a substrate for the printed electronic label.

Alternatively, the substrate is an independent flexible material (1 to 100 μm thick) serving as a mechanical support of the label, on top of which the electronic label is printed with all its components. The flexible label (plastic, paper, metal foil, rubber, self-adhesive substrate, or tattoo paper) is meant to be attached to the package with known methods.

The processing of all components and the operation of the electronic dynamic label is compatible with the low temperature budget that characterizes most of these substrates. Such label 1 comprises at least a photovoltaic source 2 adapted to supply a control module 4 and a display 6 bearing a message.

The photovoltaic source 2 is a photovoltaic module known in itself, which preferably uses a bulk heterojunction organic technology. Alternatively, the photovoltaic source is not organic, being, for example, a photovoltaic source based on quantum dots or hybrid perovskite. The photovoltaic module 2 can be printed, in a known way, on a plastic substrate, for example, PET having a thickness preferably comprised in the interval 1 μm-100 μm.

The photovoltaic (PV) module accomplish to the role of powering the printed electronic module and the printed display. Consequently its output is put in electrical contact with them through proper printed conductive lines (polymeric or metallic).

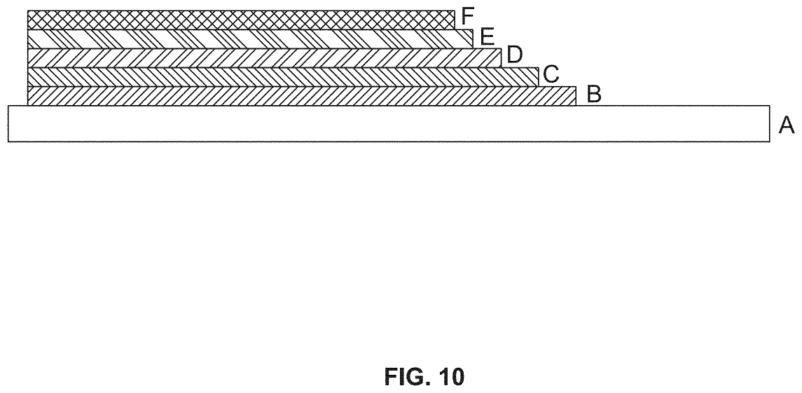

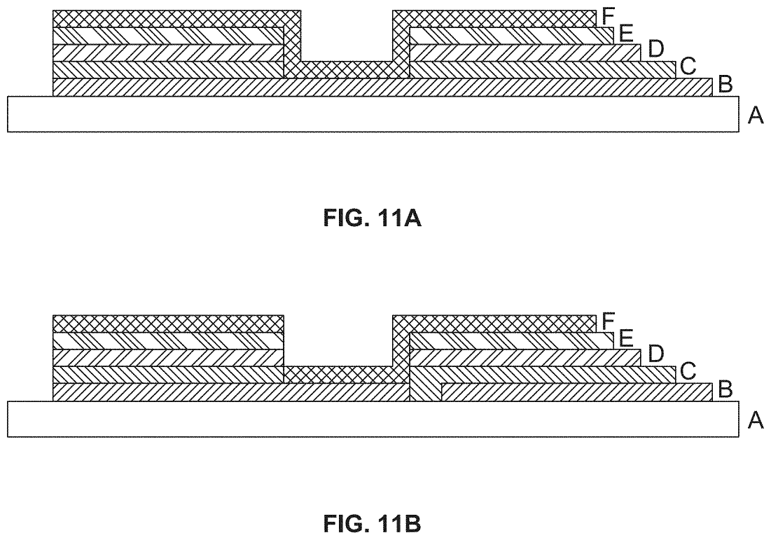

A PV module is an assembly of several photovoltaic cells (FIG. 10) electrically connected either in series (FIG. 11b) or in parallel (FIG. 11a). The sub units of a PV module are photovoltaic cells. PV cells can be assembled in series or parallel connections forming a module whose current and/or voltage is the sum of the single cells. In the case of printed PV devices there is freedom of shape in the design of the single cells and consequently the module that is made out of them.

The general structure of a PV cell (FIG. 10) is composed by at least four superimposed layers made of either conductive or semiconductive materials, on a substrate (layer A, FIG. 10). The outer layers (F, B, in FIG. 10) are the electrodes, they are made of conductive materials and their role is the one of collecting the electrical charges generated inside the inner layers and provide them to the output. At least one electrode has to be transparent or semi-transparent, in order to allow the light to reach the inner layers. In the specific case of a PV cell powering a dynamic label the transparent electrode is necessarily the one placed on the top face, meaning the side where light shines onto the label (layer F in FIG. 10). Possible examples of conductive materials compatible with the described use are metal nanoparticles, such as silver, gold, copper and aluminum, conductive metal oxides, such as indium tin oxide (ITO), aluminum doped zinc oxide (AZO), fluorine doped tin oxide (FTO), or indium gallium zinc oxide (IGZO), or conductive polymeric inks, such as poly(3,4-ethylenedioxythiophene) polystyrene sulfonate (PEDOT:PSS), polyanilines, or polypyrroles, or carbon-based compounds such as graphene, graphite, carbon black, or carbon nanotubes. All these materials can be dissolved in solvents, such as water, alcohols, or chlorinated solvents, in order to form printable inks.

The core of a PV cell is the active layer (layer D in FIG. 10) which is made of a semiconductor material with the role of absorbing the incoming light and convert it into electrical charges. Examples of semiconductive materials for active layers of printed photovoltaic devices are organic bulk heterojunctions, perovskites, quantum dots given by inorganic nanoparticles (such as silicon, CIGS, cadmium telluride, etc.). More in detail organic bulk heterojunctions refer to a blend of two or more molecular o polymeric materials where at least one component shows good electron transporting behaviour, a so-called acceptor, and at least one component shows good hole transporting behaviour. This blend is obtained by dissolving the components into a solvent, or solvents mixture, hence obtaining an ink. Examples of good electron transporting organic semiconductors working as acceptor are fullerenes, carbon nanotubes, perylene diimides, naphtalene diimides, or fused-ring acceptors. Examples of good hole transporting organic semiconductors are polythiophenes, polyphenilenevinylenes, carbazoles, phthalocyanines, or squaraines.

Finally there are other two layers, so-called interlayers, interposed between active layer and electrodes (E, C in FIG. 10) whose role is to direct positive and negative charges produced inside the active layers towards separate electrodes in order for the cell to provide an electrical voltage. These layers can be formed either by conductive or semiconductive materials. In the first case, the material can behave as electrode and interlayer hence reducing by one the overall number of layers (e.g. from five to the minimum required number of four). Examples of materials that can behave as interlayers are conductive polymers, such as PEDOT:PSS, or insulating molecules such as poly (9,9-bis(3′-(N,N-dimethylamino)propyl)-2,7-fluorene)-alt-2,7-(9,9-dioctylfluorene) (PFN), polyetherimide (PEI), or polyethylenimine (PEIE), or metal oxide nanoparticles, such as ZnO, TiO, SnO, MoO, WO, AZO, VO, CrO, or MnO, or metals, such as Ca, Al, or Ag.

In the previous paragraph the materials composing a printed PV device have been briefly described and also some examples have been provided. In order to form printable inks these materials have to be dissolved into one or more solvents. Moreover additional materials can be added to ink formulations in order to improve the printed layers performances, and a significant case is the one of dopants. The main issue associated to printed conductors and semiconductors is the structural disorder intrinsically present in any soluble materials. This limits charge mobility to low values as it translates to trapping states and/or recombination centers. A typical solution to contrast structural disorder is to perform thermal annealing of printed layers. This leads to a redistribution of domains in printed layers that increases structural and electronic order. However such strategy is limited by the properties of flexible substrates that cannot withstand high temperature for long times. For instances PET cannot withstand thermal treatments at more than 120° C., otherwise elastic deformation occurs enough to deteriorate label properties. The addition of dopants to the printed layers, obtained by printing an ink mixed with dopants, is a strategy to reduce the impact of trapping states even without performing thermal annealing on printed layers. Once added to electrically active inks, dopants releases additional charges that can move inside the conductive network and get trapped by trapping states. Occupied trapping states are neutralized hence becoming inactive towards the photogenerated charges moving inside the cell. Dopants are efficiently used both as additive to conductive and semi-conductive inks for electrodes, active layers, and interlayers. Furthermore in the case of interlayers and electrodes, the additional charge that they are providing can be useful in building an excess charge at layer interfaces with contiguous layers. This excess charge contribute to Fermi level pinning at the interface that strongly reduces recombination at the interface and maximizes the open circuit voltage of solar cells.

FIG. 2 shows a front view of an embodiment of the label 1 in which there are a plurality of photovoltaic modules 2 arranged along a circumference, the display 6 corresponding to the area containing the message and the control module 4 being next to the display 6 (alternatively, the control module 4 is positioned below the display 6 as described in detail below).

In a preferred embodiment of the present invention an electronic label integrates at least one printed display. The display can be formed by one or multiple elements, known as “pixels”. The display is meant to provide a visible feedback, realizing a dynamic graphical element on the label. Such feedback can be constituted by a single pixel blinking (i.e. changing its color at a specific frequency), or by a set of pixels blinking at the same time or at different times set in the control unit. In the latter case, the display can be made for example by sub-parts or segments composing overall an image, a letter, a phrase, a number, a series of numbers, an alphanumeric code.

The fundamental operation of the printed display is based on an electrically addressable layer of a printable ink, i.e. the active material of the display, as the rest of its components, is printable. The specific nature of the ink and the specific architecture of pixel(s) depends on the chosen technology, compatible with the invention. While the general architecture and the integration of the display within the label is common to all solutions.

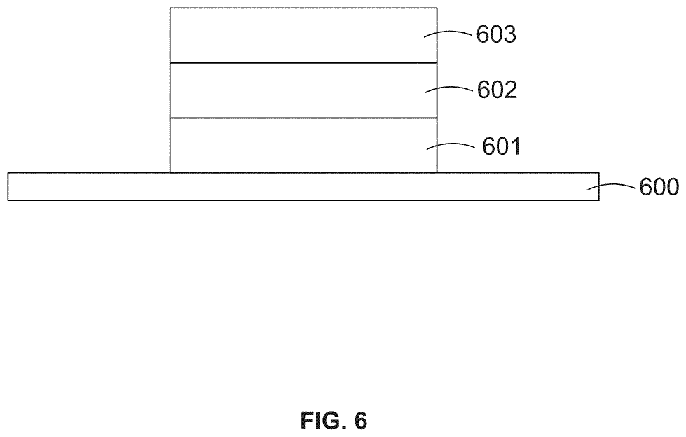

One pixel is composed at least by three printed layers on the substrate (layer 600, FIG. 6), realizing a sandwich structure: two external conductive layers (601 and 603 in FIG. 6, made of conductive inks comprising metal nanoparticles, such as silver, gold, copper and aluminum, or conductive polymeric inks, such as PEDOT:PSS, polyanilines, or polypyrroles, or carbon-based compounds such as graphene, graphite, carbon black, or carbon nanotubes), and an internal layer (602, either an ion reservoir or a semiconducting emissive layer). At least external layer 603 is transparent or semi-transparent. The pixel can be electrically addressed by applying either a voltage difference between layers 601 and 603 or a current, depending on the specific nature of the electrically addressable printed ink. The application of the input signal is allowed by printed interconnection traces (metallic e.g. Ag or Cu, or polymeric, e.g. PEDOT:PSS) connecting one output of the control module (the control module has at least one output) to the pixel (the display has at least one pixel).

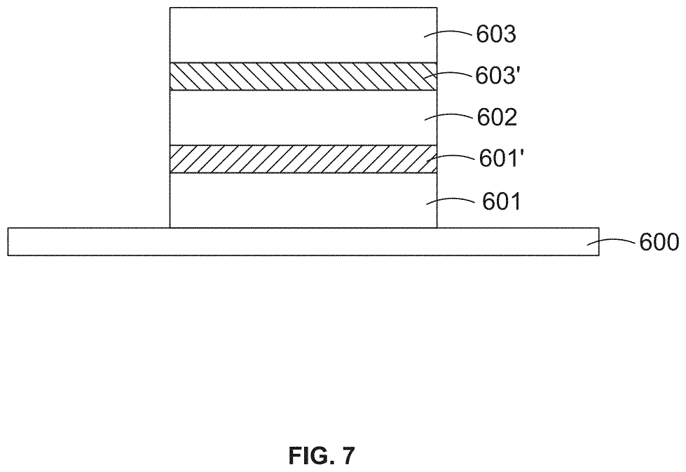

The basic pixel can foresee the presence of two additional injection layers 601′ and 603′ in FIG. 7. At least layer 603′ is transparent or semi-transparent.

The invention identifies two printed display technologies: electrochromic and electroluminescent. They both share the same basic architecture and integration within the label. The two technologies are characterized by different printable functional inks.

In the electrochromic (EC) case, layer 601 or layer 603 is made of a printable electrochromic material (e.g. PEDOT:PSS or other PEDOT based materials, or other polymer EC materials, or other small molecules EC materials that can be printed). Conversely, layer 603 or 601 is made of a printed conductor, transparent or opaque, made for example of PEDOT:PSS, carbon based inks, silver, or copper. Layer 602 is made of an electrolyte, acting as an ion reservoir. The switching occurs by connecting the PV panel output through the control to the pixel: the photogenerated charge flows at a specific voltage, producing the change in oxidation state of layer 601 or layer 603, and redistribution of ions from layer 602. As an effect, the color of reflected light changes, as the pixel typically changes its transparency.

In an electroluminescent device, layers 601 and 603 are conductive electrodes (typically metallic, or metallic grids, or polymeric), and layer 602 is made of a printable light emitter (including printable light-emitting polymers, small molecules, blends, quantum dots, or perovksites). The switching in color occurs by connecting the PV panel output through the control to the pixel: a controlled current flows through the pixel, and electrons injected from one side (e.g. 601) and holes injected from the other (e.g. 603) recombine in layer 602 to produce emission of a photon, whose color depends on the specific emitter. More efficient pixels foresee 601′ and 603′ injection layers to balance holes and electrons injection (FIG. 7).

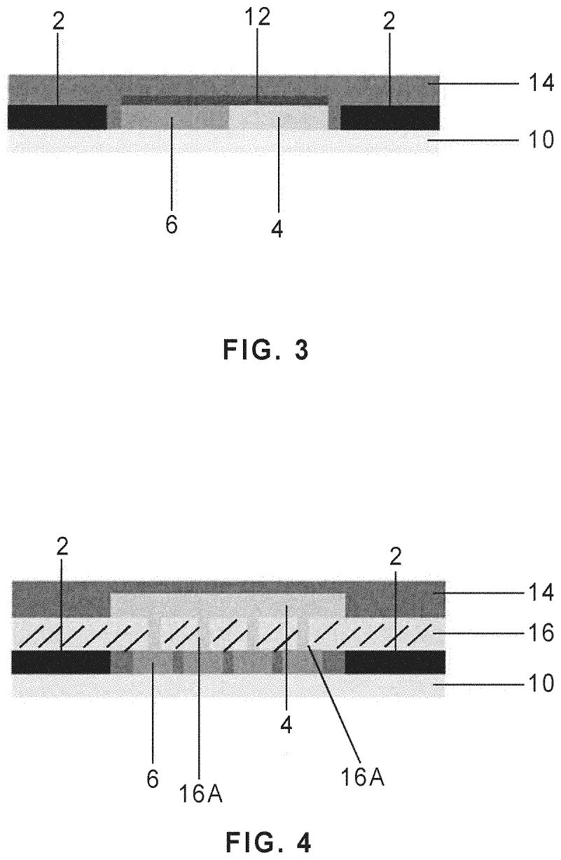

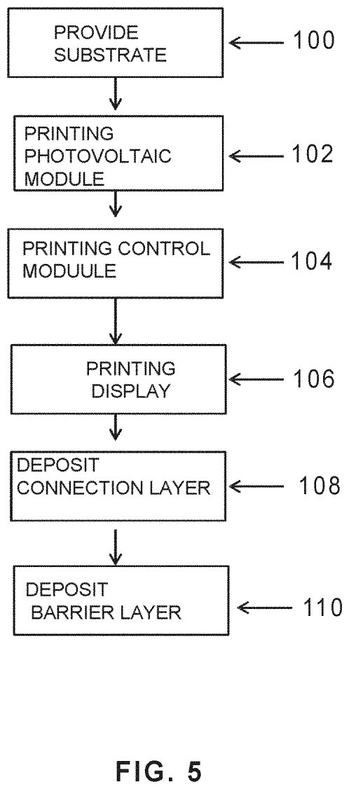

Below, with reference to FIGS. 3 and 4, the process will be described for obtaining a label according to the present invention, the block diagram of which is shown in FIG. 5. Such a procedure starts with a first step 100 of providing a substrate 10, preferably of the type described above. Such substrate 10 may be transparent or opaque. In an embodiment of the present invention, the label is printed directly on the packaging (e.g. a plastic bottle or paper box), in which case the substrate is the surface of the packaging itself. Alternatively the substrate could be made of (or including) other materials, e.g. metal foils, rubber, self-adhesive substrate, or tattoo paper.

FIG. 3 shows a sectional view of the label 1 in which the substrate 10 is present, preferably a plastic sheet or bottle, onto which, in step 102 the photovoltaic module is printed. Between the photovoltaic modules 2 in steps 104 and 106 the control module 4, preferably comprising at least a low power supply thin film transistor, and the display 6 are printed, respectively, the latter preferably provided in the form of a layer of electrically addressable material, e.g. an electrochromic material. Alternatively the layer could be made of any other electrically addressable material, e.g. an electroluminescent material.

A fundamental limit connected with organic electronic printing (steps 102-106 described above) on thin (10-200 μm) and ultrathin (less than 10 μm) plastic supports is connected with the maximum temperature of the printing process. Typically, to perform such printing, thermal heating processes are required, which are not compatible with the thin layer of plastic substrate used in the packaging, since such a layer would be heat sensitive. The optimisation of the organic electronic printing process is closely connected with the annealing processes, which typically require temperatures of over 100° C., necessary for optimising the performance of the printed devices, for example, improving the mobility of charge carriers, de-absorbing contaminants and obtaining the desired morphology of the support layer.

In the printing operations 102-106 described above, ink is used which is in itself known, to which, before performing the printing itself, dopants are added, preferably precursors of benzimidazole and benzimidazoline, or caesium or lithium salts.

Thanks to the use of these particular chemical dopants, optimised electronics are obtained, printed directly at room temperature or however at low temperatures compatible with the substrate 10 (preferably lower than 70° C.), in which only the evaporation of the ink solvent is required.

The control module 4 is provided to send control signals to the display 6 so that predetermined messages are shown on the display 6.

The control module 4 and the display 6 are in electrical contact with the photovoltaic module 2 for allowing its supply by the latter.

Above the control module 4 and the display 6, in step 108, an electrical lateral interconnecting layer 12 is deposited, preferably of ion-gel or solid electrolyte type, which allows the control module 4 to perform a low voltage control of the display 6, i.e. allowing the control module 4 to send control signals to the display 6.

Alternatively, the control module 4 is provided through at least one thin film transistor comprising semiconductor metal oxides such as, for example, ZnO, indium zinc oxide (IZO), or IGZO.

A printed control module is an active system that provides an electrical signal to allow the display to properly show relevant information on the active label. It can be thought as the intelligent core of the label that enables active communication with the external world.

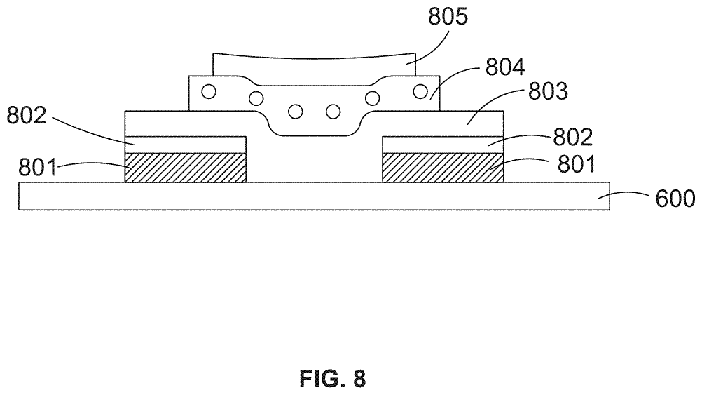

Such control module embodies one or multiple printed active devices in a TFT (Thin Film Transistor) configuration, properly connected so to realize a predefined logic function (e.g. oscillators, counters, or shift registers) and power function (e.g. display driving). Printed TFT devices are realized in a four or five layer configuration (FIG. 8) comprising: i) two electrodes, defined as source and drain electrodes, made by printed conductors (e.g. silver, copper, gold, PEDOT:PSS, graphene, carbon nanotubes (CNTs), or metal oxides) where the electrode distance is defined as channel length (L) and the electrode-electrode facing area is defined as channel width (W) (layer 801 in FIG. 8); i. a printed injection layer containing an organic or inorganic dopant compound (e.g. benzimidazoline, benzimidazole, caesium salts, lithium salts, etc.) dissolved or dispersed in a solvent or polymer matrix (layer 802 in FIG. 8); ii) a printed semiconducting layer (803 in FIG. 8, organic polymers or blends of such, organic small molecules or blends of such, blend of organic polymers and small molecules, metal oxides, CNTs, IGZO, zinc tin oxide (ZTO), etc.) in which specific negative (n-type semiconductor) or positive (p-type semiconductor) electric charge can be created by means of an external electrode (gate); iii) a printed gating layer (804 and 805 in FIG. 8). The gating layer (i.e. gate) itself is composed by a two layer stack comprising: i) a printed insulating layer (e.g. organic polymers, metal oxides, etc.) or an electrolyte layer (polyelectrolytes, solid electrolytes, or ion gels) (804 in FIG. 8); ii) a printed gate electrode made by printed conductors (e.g. silver, copper, gold, PEDOT:PSS, graphene, CNTs, or metal oxides) (805 in FIG. 8).

In order to form printable inks these materials have to be dissolved into one or more solvents. Additional materials can be added to ink formulations in order to improve the printed layers performances, and a significant case is the one of dopants. The main issue associated to printed conductors and semiconductors is the structural disorder intrinsically present in any soluble materials. This limits charge mobility to low value as it translates to trapping states and/or recombination centers. A typical solution to contrast structural disorder is to perform thermal annealing of printed layers. This leads to a redistribution of domains in printed layers that increases structural and electronic order. However such strategy is limited by the properties of flexible substrates that cannot withstand high temperature for long times. For instance PET cannot withstand thermal treatments at more than 120° C., otherwise elastic deformation occurs enough to deteriorate label properties. The addition of dopants to the printed layers, obtained by printing an ink mixed with dopants, is a strategy to reduce the impact of trapping states even without performing thermal annealing on printed layers. Once added to electrically active inks, dopants release additional charges that can move inside the conductive network and get trapped by trapping states. Occupied trapping states are neutralized hence becoming inactive towards the injected charges. Dopants are efficiently used both as additives to injection layers (802 in FIG. 8) and to semiconducting layers (803 in FIG. 8). In injection layers they can both increase the conductivity of the layer and reduce the barrier for charge injection from electrodes. For the semiconducting layer, a low level of doping fills traps and allow the injected carrier from the electrode or from the injection layer to move along higher mobility states.

The control module takes its supply voltage from the Printed Photovoltaic Module and delivers as output a specific voltage and/or current to the printed display.

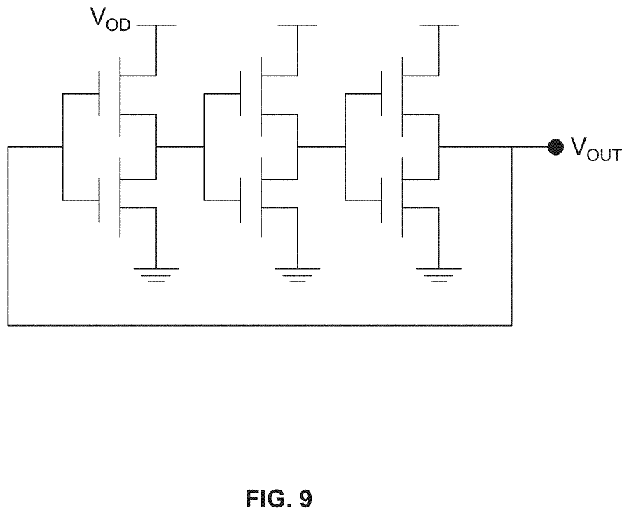

A simple control module may be constituted by a minimum set of TFT devices composed so that a basic logic function may be realized. As an example, such control module is a simple oscillator that gives a certain voltage to a display driver. An oscillator can be realized with TFT of different polarities (both n-type and p-type) whose configuration is known as complementary, as illustrated in FIG. 9. Such configuration allows any intermediate node of the circuit to provide an oscillating voltage and embodies the simplest configuration for an oscillator. In order to properly provide the oscillating signal to the display module, a power TFT or power circuit comprising more TFTs, is needed since display module pixels can have high voltage or high current requirements. Such power TFT is realized with the same configuration described above for a single TFT, but with appropriately designed W and L dimensions so the necessary current and/or capacitance driving capability is achieved.

Despite being composed by three electronic devices with specific functions, a dynamic label is a monolithic device (FIG. 1 and FIG. 2) where the sub-devices are put into electrical connection with each other and they can also share some composing layers.

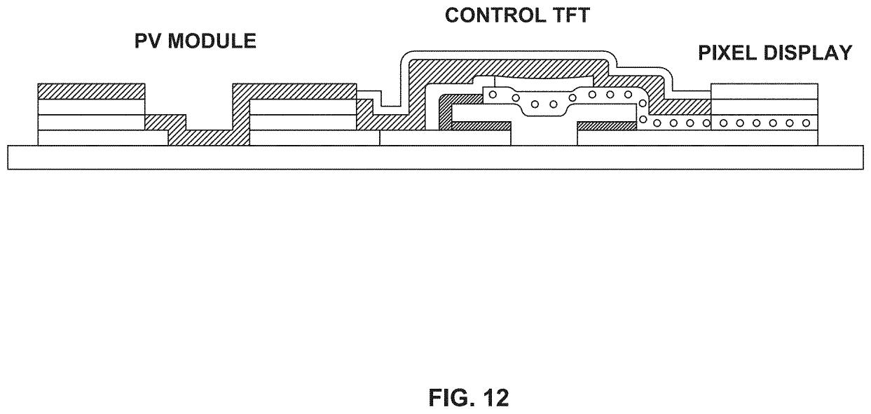

Represented in FIG. 12 is an example of possible interconnections among different devices. The electrical connection among the sub-devices is provided by printed conductive lines made by the conductive inks previously described. The photovoltaic module is the one providing power to both the control module and the display. The control module power lines are always connected to the PV module, therefore the control module is always on when the label, and therefore the PV module is exposed to light (indoor or outdoor). Instead, the display is powered through the control module output that decides when to switch the display elements on and off.

The PV module, the control module and the display all foresee printed conductive layers. One relevant implementation of the present invention is to realize both the modules electrodes and the connecting lines with the same materials, hence requiring one single printing step for all of them. Another printing step that can be shared among different modules is the deposition of n-type and p-type semiconductive inks working both as interlayers for the photovoltaic module and charge injection layers in the transistors composing the control module. Finally the same solid state electrolyte used in the EC display can be the electrolytic gate of electrolyte gated TFTs in the control module.

The possibility to share these layers among the different modules is meant to reduce the printing steps and consequently the overall complexity of the fabrication process. However on the contrary this does not exclude that the devices can be realized through separates printing steps.

Finally, in step 110, on top of all the underlying layers, a barrier layer 14 is deposited, preferably oxide/polymer multilayer, for example silica and alumina for the inorganic layer and ethylene vinyl acetate (EVA), ethylene tetrafluoroethylene (ETFE), PET or polyethylene naphthalate (PEN) for the organic layer, so as to protect the underlying layers from oxygen and water vapour.

FIG. 4 shows a variation of the invention wherein similar layers are indicated with the same reference numbers. In this variation, only the display 6 is placed between two photovoltaic modules 2 above the substrate 10 and not also the control module 4. Above the photovoltaic modules 2 and the display 6 an insulating layer 16 is first deposited, having a predetermined pattern, i.e. a plurality of holes 16a placed in correspondence of the display 6 and subsequently the control module 4 is deposited which, through the holes 16a, comes into contact with the display 6 below. Finally, above the control module 4 the barrier layer 14 is deposited.

Therefore, in this embodiment, during use, there will be the front display 6 and the control module 4 behind it.

The label 1 according to the present invention is recyclable because all the electronic components are made with plastic electronic materials or easily separable from plastic (metallisations of silver or other metals).

The active label 1 is also recyclable because the materials of which each of its components are comprised, i.e. the photovoltaic module 2, the control module 4 and the display 6 are characterised by a low melting temperature (comprised between 200 and 400° C.). In this way, any traces of non-plastic materials (metals, metal oxides, etc.) present in the label 1 can be removed by filtering, in a known way, through techniques for the purification of recycled plastic.

In view of the aforementioned, in an embodiment, the present disclosure pertains to a packaging label including a flexible substrate and a display printed on the flexible substrate. In some embodiments, the display includes an electrically addressable layer of printable ink. In some embodiments, the display includes an electrically addressable layer of printable ink and other components. In some embodiments, the display includes only an electrically addressable layer of printable ink. In some embodiments, the packaging label includes a control module printed on the flexible substrate, the control module being in electrical contact with the display and arranged to control operation of the display. In some embodiments, the control module has a layer including at least one printing ink mixed with dopants that limit printing temperature such that evaporation of only ink solvent is required for printing, and at least one photovoltaic module printed on the flexible substrate and next to the display and arranged to supply voltage to the display and the control module, the photovoltaic module having a layer having at least one printing ink mixed with dopants that limit printing temperature such that evaporation of only ink solvent is required for printing.

In some embodiments, the flexible substrate is made of at least one material including, without limitation, plastic, paper, metal foils, rubber, self-adhesive substrate, or tattoo paper. In some embodiments, the printable ink of the display is electrochromic. In some embodiments, the flexible substrate has a thickness between 1 and 100 μm. In some embodiments, the dopants can include, without limitation at least one precursor of benzimidazole, at least one precursor of benzimidazoline, a caesium salt, a lithium salt, and combinations thereof. In some embodiments, the electric contact between the control module and the display includes an inter-connecting layer of ion-gel or solid electrolyte, the inter-connecting layer having at least one function of an ion reservoir for the display and a gate medium for transistors in the control module.

In some embodiments, the control module includes a low-voltage organic thin layer transistor. In some embodiments, the control module includes at least a thin film transistor including semiconductor metal oxides. In some embodiments, the packaging label includes a barrier layer placed above the control module. In some embodiments, the packaging label includes an insulating layer placed above the display and on which the control module is placed, the insulating layer having a plurality of holes placed in correspondence of the display and arranged to allow the electric contact between the display and the control module. In some embodiments, the at least one photovoltaic module is a plurality of photovoltaic modules arranged along a circumference of the flexible substrate.

In an additional embodiment, the present disclosure pertains to a method of forming a packaging label for a package. In some embodiments, the method includes printing on a substrate at least one photovoltaic module and printing a control module and a display in electrical contact with the at least one photovoltaic module. In some embodiments, the display includes an electrically addressable layer of printable ink. In some embodiments, the display includes an electrically addressable layer of printable ink and other components. In some embodiments, the display includes only an electrically addressable layer of printable ink. In some embodiments, the method includes depositing on the control module and the display an electrical lateral interconnecting layer arranged to allow the control module to control the display. In some embodiments, the at least one photovoltaic module is arranged to supply voltage to the display and the control module. In some embodiments, the printing steps of the photovoltaic module, the control module, and the display include the step of mixing a printing ink with dopants that limit printing temperature such that evaporation of only ink solvent is required for printing.

In some embodiments, the method includes the step of forming a barrier layer arranged to protect underlying layers. In some embodiments, the method includes depositing an insulating layer above the display so as to place the control module above the insulating layer, the insulating layer having a plurality of holes placed in correspondence of the display and arranged to allow the display to electrically contact the control module. In some embodiments, the substrate is a surface of the package.

In an additional embodiment, the present disclosure pertains to a packaging having a label printed via the aforementioned method.

Naturally, various modifications to the principle of the invention, the embodiments and construction details may be possible, according to what is described and disclosed merely by way of non-limitative example, without departing from the scope of the present invention, as defined by the appended claims.

What is claimed is:

1. A packaging label comprising:
a flexible substrate;
a display printed on the flexible substrate, the display consisting of an electrically addressable layer of printable ink;
a control module printed on the flexible substrate, the control module being in electrical contact with the display and arranged to control operation of the display, the control module having a layer consisting of at least one printing ink mixed with dopants that limit printing temperature such that evaporation of only ink solvent is required for printing; and
at least one photovoltaic module printed on the flexible substrate and next to the display and arranged to supply voltage to the display and the control module, the photovoltaic module having a layer consisting of at least one printing ink mixed with dopants that limit printing temperature such that evaporation of only ink solvent is required for printing.

2. The label according to claim 1, wherein the flexible substrate is made of at least one material selected from the group consisting of plastic, paper, metal foils, rubber, self-adhesive substrate, or tattoo paper.

3. The label according to claim 1, wherein the printable ink of the display is electrochromic.

4. The label according to claim 1, wherein the flexible substrate has a thickness between 1 and 100 μm.

5. The label according to claim 1, wherein the dopants are selected from the group consisting of at least one precursor of benzimidazole, at least one precursor of benzimidazoline, a caesium salt, a lithium salt, and combinations thereof.

6. The label according to claim 1, wherein the electric contact between the control module and the display comprises an inter-connecting layer of ion-gel or solid electrolyte, the inter-connecting layer having at least one function of an ion reservoir for the display and a gate medium for transistors in the control module.

7. The label according to claim 1, wherein the control module comprises a low-voltage organic thin layer transistor.

8. The label according to claim 1, wherein the control module comprises at least a thin film transistor comprising semiconductor metal oxides.

9. The label according to claim 1, comprising a barrier layer placed above the control module.

10. The label according to claim 1, comprising an insulating layer placed above the display and on which the control module is placed, the insulating layer having a plurality of holes placed in correspondence of the display and arranged to allow the electric contact between the display and the control module.

11. The label according to claim 1, wherein the at least one photovoltaic module is a plurality of photovoltaic modules arranged along a circumference of the flexible substrate.

12. A method of forming a packaging label for a package, the method comprising:
printing on a substrate at least one photovoltaic module;
printing a control module and a display in electrical contact with the at least one photovoltaic module, wherein the display consists of an electrically addressable layer of printable ink;
depositing on the control module and the display an electrical lateral interconnecting layer arranged to allow the control module to control the display, wherein the at least one photovoltaic module is arranged to supply voltage to the display and the control module; and
wherein the printing steps of the photovoltaic module, the control module, and the display comprise the step of mixing a printing ink with dopants that limit printing temperature such that evaporation of only ink solvent is required for printing.

13. The method of claim 12, comprising the step of forming a barrier layer arranged to protect underlying layers.

14. The method according to claim 12, comprising depositing an insulating layer above the display so as to place the control module above the insulating layer, the insulating layer having a plurality of holes placed in correspondence of the display and arranged to allow the display to electrically contact the control module.

15. The method of claim 12, wherein the substrate is a surface of the package.

16. A packaging comprising a label printed with the method of claim 15.
